(19) United States
(12) Patent Application Publication
(10) Pub. No.: US 2024/0409374 A1
(43) Pub. Date: Dec. 12, 2024

(54) TEMPERATURE-CONTROL DEVICE FOR A HANDRAIL OF AN ESCALATOR OR A MOVING WALKWAY

(71) Applicant: Inventio AG, Hergiswil (CH)

(72) Inventor: Chen JIAO, Shanghai (CN)

(21) Appl. No.: 18/702,133

(22) PCT Filed: Oct. 17, 2022
(86) PCT No.: PCT/EP2022/078757

§ 371 Date: Apr. 17, 2024

(30) Foreign Application Priority Data
Oct. 26, 2021 (EP) 21204664.3

(51) Int. Cl. B66B 31/02; B66B 23/24; G05D 23/19; H10N 10/13

(52) U.S. Cl. CPC B66B 31/02; B66B 23/24; G05D 23/1919; H10N 10/13

(57) ABSTRACT

The disclosure relates to a handrail temperature-control device for a handrail of an escalator or a moving walkway. The handrail temperature-control device has a base, a roller arrangement which is arranged on the base, and a semiconductor cooling element, the semiconductor cooling element being arranged in a recess between the base and the roller arrangement.

### TECHNICAL FIELD

The present disclosure relates to a handrail temperature-control device for a handrail of an escalator or a moving walkway.

### SUMMARY

Escalators and moving walkways have been used as conveyor systems to transport people in public spaces for more than a hundred years. Places of use in this regard are department stores, shopping malls, airports, railway stations, subway stations, amusement parks, and the like. Such conveyor systems are usually arranged and operated in air-conditioned interiors, usually protected from direct sunlight, so that the climatic ambient conditions have little impact on ride comfort.

Escalators and moving walkways can also be installed completely outdoors or partially protruding from buildings. The escalators and moving walkways used outdoors present the problem that their handrails heat up under solar radiation. This heating up causes the use of the handrail to be perceived as uncomfortable. People therefore often refrain from holding onto the heated-up handrail when using an escalator or a moving walkway. This increases the risk of falls.

In hot and dry countries, a handrail exposed to direct solar radiation can heat up to temperatures of up to 75° C. In particular, if the handrail is heated up significantly, there is a risk that people may sustain burns when they come into contact with the handrail that has been heated up in this way.

The problem of handrails of escalators or moving walkways heating up is aggravated by the fact that the handrails are usually made of synthetic rubber or various plastic mixtures. The black color of the handrails amplifies the heating effect. Rubber or plastics are poor heat conductors (lambda of approximately 0.16-0.27 W/m K). Therefore, once a handrail has heated up, it can only be cooled down slowly or by means of large temperature differences.

In addition, when escalators or moving walkways are started, additional energy is introduced into the handrail by the drive and by frictional heat on the sliding guide rails. Heating of the handrail is further promoted by the fact that more and more escalators are being switched from continuous operation to intermittent operation in order to save energy. This means that the escalator is stationary as long as no person is using the escalator. During this period of standstill, the so-called handrail advance is completely exposed to the sun. In contrast, the so-called handrail return is contrastingly exposed to only the ambient temperature in the interior of the supporting structure.

In order to counteract the heating of the handrail, cooling can be provided for the handrail. Escalators having a cooling device for cooling the handrail are known from the prior art.

Accordingly, the document JP 2007 238309 A discloses an escalator having a cooling system for the handrail in which a cold air flow is generated by means of an air conditioner. The entire returning handrail is cooled via an insulated channel. The cooling system is a closed cooling system. Sensors regulate the cooling so that the handrail temperature is permanently kept below a defined value. With such a system, air temperature differences of approx. 5° C. can be achieved. The difference between the cooling air and the ambient temperature is relatively small so that cooling the handrail takes a relatively long time. Furthermore, the design of systems is large, and a high noise level is generated by the fans and the blower. The energy consumption for the entire cooling system is also high.

Furthermore, an escalator with a cooling system for cooling the handrail is also known from JP 2000 263655 A. In this case, alcohol is sprayed onto the handrail by means of compressed air. Fans behind the alcohol spray system promote evaporation of the alcohol, so that evaporative cooling arises by means of which the handrail is cooled. Since alcohol is flammable, the use of alcohol is not unproblematic. In addition, a comparatively small temperature difference between the coolant applied to the handrail and the ambient temperature can be achieved. Cooling down a handrail therefore takes a relatively long time. This solution also has the disadvantage that consumables (alcohol) must be continuously provided. The proposed solution significantly increases operating costs and the time expended in maintenance. JP 2017 081678 A, JP 6 039037 B1 and DE 10 2015 212483 A1 disclose further cooling systems for handrails.

The object of the present disclosure is therefore to provide a handrail temperature-control device that generates minimal operating noise, requires no consumables and still ensures adequate temperature control of the handrail.

This object is achieved by a handrail temperature-control device for a movably arranged handrail of an escalator or a moving walkway. The handrail temperature-control device can comprise, in particular, a base, a roller arrangement which can be arranged on the base, and a semiconductor cooling element. The semiconductor cooling element can be arranged in a recess between the base and the roller arrangement.

Semiconductor cooling elements, also referred to as Peltier elements, have been known for decades and are used in many fields, such as in automotive refrigerators, external cooling devices for cell phones, cold compresses, and the like. In some embodiments, the semiconductor cooling elements can generate a temperature difference of more than 60 Kelvin from the ambient temperature. As a result of the arrangement of the semiconductor cooling element, it can cool down the roller arrangement on the one hand and release its heat to the base on the other hand. The roller arrangement can enable direct surface contact between the handrail temperature-control device and the surface of a handrail to be cooled down, so that excellent heat transfer between the roller arrangement and the handrail is achieved with minimum friction resistance and wear.

As is explained herein, the handrail temperature-control device can also be used to heat the handrail in cold ambient temperatures. For the sake of clarity, the device is described hereinafter almost entirely as a cooling device. However, this description should not be seen as limiting the scope of the present disclosure.

In some embodiments of the handrail temperature-control device, the roller arrangement can comprise a roller frame and a plurality of rollers which are arranged rotatably mounted in the roller frame side by side and parallel to one another with respect to their axes of rotation. This design can allow the rollers in the roller frame to be mounted precisely and therefore at the smallest possible distance from one another so that the rollers effectively create a surface over which the handrail is to be guided. Its direction of movement can be orthogonal to the axes of rotation of the rollers. The surface formed by the rollers can also be convexly curved toward the handrail with respect to the intended direction of passage of the handrail so that a sufficient pressing force can be achieved between the rollers and the handrail guided over them.

In some embodiments of the handrail temperature-control device, the roller frame can frame the rollers laterally, wherein cylindrical surfaces of the rollers may protrude beyond at least one side surface of the roller frame. This side surface can effectively surround all the rollers. The protruding regions of the cylindrical surfaces and the side surface can be provided to be mounted facing a handrail in an escalator or in a moving walkway. This may ensure that the handrail to be guided over the rollers does not touch the roller frame arranged in a stationary manner in the escalator or in the moving walkway, and thereby removes material from the handrail.

In some embodiments of the handrail temperature-control device, the base can be made of a thermally conductive material and can have a support member and a heat dissipation structure. The heat dissipation structure can be arranged on a side of the support member facing away from the roller frame so that the heat to be released is released into the ambient air as far away from the handrail as possible. The heat dissipation structure can be an arrangement of cooling fins or cooling pins which increase the surface of the support member and thus the heat radiation surface. However, the heat dissipation structure can also have other characteristics and, for example, be designed as an air or water heat exchanger. The heat dissipation structure can also be a heat pipe, with which the heat or waste heat to be dissipated from the heated side of the semiconductor cooling element in operation can also be guided outside a cladding of an escalator or a moving walkway and can be released into the ambient air.

In some embodiments of the handrail temperature-control device, the support member can have a support surface and at least one projection, the projection being arranged on the support surface in side regions of the support member. The at least one projection may serve to attach the roller frame at a predetermined distance from the support surface and therefore protrudes from the support surface in a direction facing away from the heat dissipation structure. As a result of its arrangement in the edge region, it may form a recess in the base and at least partially border the recess. In this case, the dimensions of the recess can be configured such that at least one semiconductor cooling element can be arranged therein. Since the heat is released to the base and this makes the base hot, a heat-insulating layer can be provided between the at least one projection and the roller frame. Of course, the roller frame itself can be made of a heat-insulating material.

In some embodiments of the handrail temperature control device, at least two semiconductor cooling elements can be arranged in the recess since these are mass-produced, and can have a thickness of 3 mm to 10 mm, and a square base with an edge length of 20 mm to 90 mm.

The heat may be exchanged between the cold side of the semiconductor cooling element in operation and the rollers primarily via thermal radiation. In order to ensure the best possible heat transfer, the cylindrical surfaces of the rollers can be arranged as close as possible to the semiconductor cooling element. Since the semiconductor cooling element has a plate-like structure, the roller frame, the diameters of the rollers, and the at least one projection can be coordinated with one another in such a way that the cylindrical surfaces of the rollers have a minimum distance of 0.0001 mm to 0.5 mm, preferably 0.001 mm to 0.2 mm, or 0.01 mm to 0.1 mm, from the cooling surface of the semiconductor cooling element arranged in the recess. When designing the minimum distance, the manufacturing tolerances and flatness of the components can also be taken into account so that the rollers do not touch the cooling surface and the manufacturing costs can still be kept low.

So that as much heat as possible can be transferred from the handrail to the semiconductor cooling element, the rollers can have good thermal conductivity. The rollers are therefore preferably chiefly made of copper, a copper alloy, aluminum, or an aluminum alloy.

Since the heat may be transferred from the rollers to the cooling side primarily via thermal radiation, the rollers can have a black coating at least on their cylindrical surface.

As stated above, the embodiments of the handrail temperature-control device disclosed herein are primarily intended for cooling handrails of an escalator or a moving walkway. Escalators or moving walkways have at least one balustrade with a handrail arranged circulating around the balustrade. According to the disclosure, at least one handrail temperature-control device with its roller arrangement can be arranged under the handrail for at least one of the existing handrails to cool its grip surface. In this case, the grip surface of the handrail can be guided over the roller arrangement and can be in contact therewith.

In some embodiments of the escalator or the moving walkway, the at least one handrail temperature-control device can be arranged upstream relative to a starting point of the passenger touching the handrail belt along a direction of movement of the circulating handrail. In other words, the handrail temperature-control device can be placed such that it is not too far away from the point at which a passenger grips the handrail. Preferably, the assembly instructions for assembling the handrail temperature-control device specify that the distance between the handrail temperature-control device and the starting point along the direction of movement of the handrail belt may be within a certain range so that the handrail does not already seem too warm for the user.

In some embodiments of the escalator or the moving walkway, at least two handrail temperature-control devices can be provided per existing handrail which are arranged at intervals along the direction of movement of the handrail. This serial arrangement may allow the handrail to be cooled down in an energy-efficient manner to suit the prevailing climate, in that, for example, one of the two handrail temperature-control devices may be operated when there is less solar radiation.

In some embodiments of the escalator or the moving walkway, the handrail temperature-control device can have a current supply provided to supply current to the semiconductor cooling element. In addition, the handrail temperature-control device can have a temperature-regulating module configured to regulate the output power of the current supply to be supplied to the semiconductor cooling element. In other words, the temperature-regulating module may regulate the output power of the current supply or the electrical energy to be supplied to the semiconductor cooling element over time.

In some embodiments of the escalator or the moving walkway, the temperature-regulating module can comprise a handrail temperature measurement sensor and a processor. The handrail temperature measurement sensor can be used is this case to measure the temperature of the handrail. The temperature may be expediently measured at a point of the handrail which is arranged between the handrail temperature-control device and the starting point described above so that the temperature of the cooled down grip surface can be detected. The processor may process the measurement signals transmitted to it from the handrail temperature measurement sensor and can be configured to regulate the output power of the current supply transmitted to the semiconductor cooling element as a function of the temperature of the handrail measured by the handrail temperature measurement sensor. This can allow the temperature of the handrail to be regulated in such a way that it creates a pleasant feel for the passenger.

The feel of the handrail also depends on the ambient temperature of the escalator or the moving walkway. If the handrail is cooled down too much compared to the ambient temperature, the passenger may perceive it as too cold and will not hold on to the handrail either. In addition, excessive cooling consumes a lot of electrical energy without achieving the intended benefit. In order to avoid this situation, the temperature-regulating module can comprise an ambient temperature measurement sensor, the ambient temperature measurement sensor configured to measure the ambient temperature of the escalator or the moving walkway. The processor can be configured here to regulate the output power of the current supply transmitted to the semiconductor cooling element as a function of a predetermined difference to the outside temperature and taking into account the temperature of the handrail measured by the handrail temperature measurement sensor.

### BRIEF DESCRIPTION OF THE DRAWINGS

Embodiments of the present disclosure will be described herein with reference to the accompanying drawings, wherein neither the drawings nor the description are intended to be interpreted as limiting the disclosure. Furthermore, the same reference signs are used for elements that are identical or have the same effect. In the drawings:

FIG. 1: shows a side view of a handrail temperature-control device;

FIG. 2: shows a cross-section along the line A-A through the handrail temperature-control device of FIG. 1;

FIG. 3: shows a top view of the handrail temperature-control device shown in FIGS. 1 and 2;

FIG. 4: shows a three-dimensional view of a semiconductor cooling element which is part of the handrail temperature-control device shown in FIG. 1 to 3;

FIG. 5: shows a three-dimensional view of a roller arrangement which is part of the handrail temperature-control device shown in FIG. 1 to 3;

FIG. 6: shows a three-dimensional view of a base which is part of the handrail temperature-control device shown in FIG. 1 to 3;

FIG. 7: shows a three-dimensional view of a possible arrangement of the handrail temperature-control device shown in FIG. 1 to 3 in an escalator, which is only shown in part.

### DETAILED DESCRIPTION

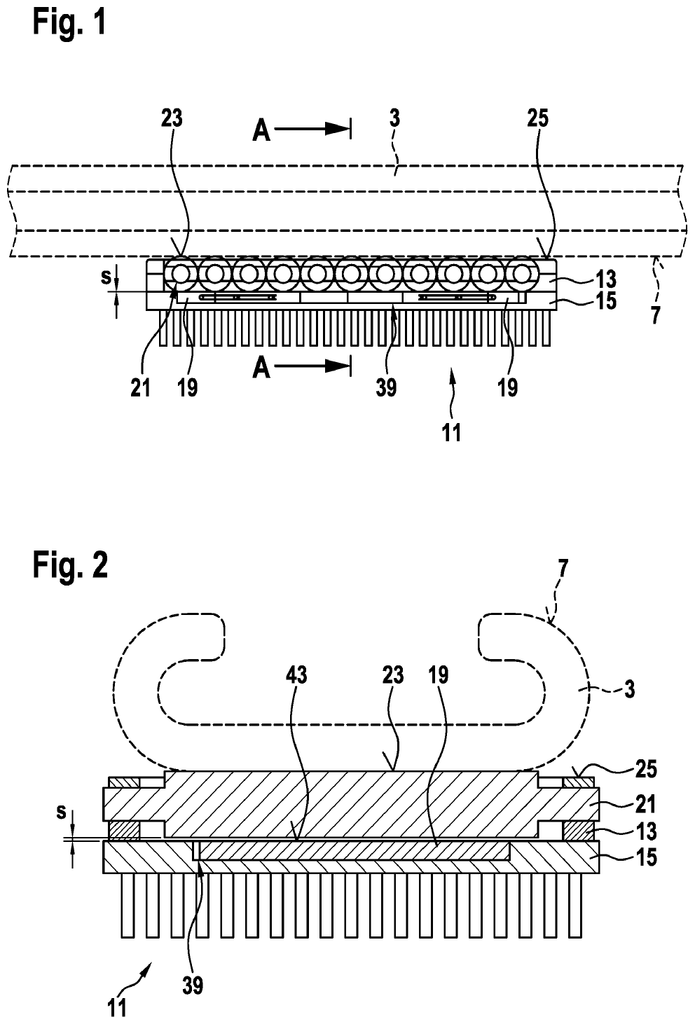

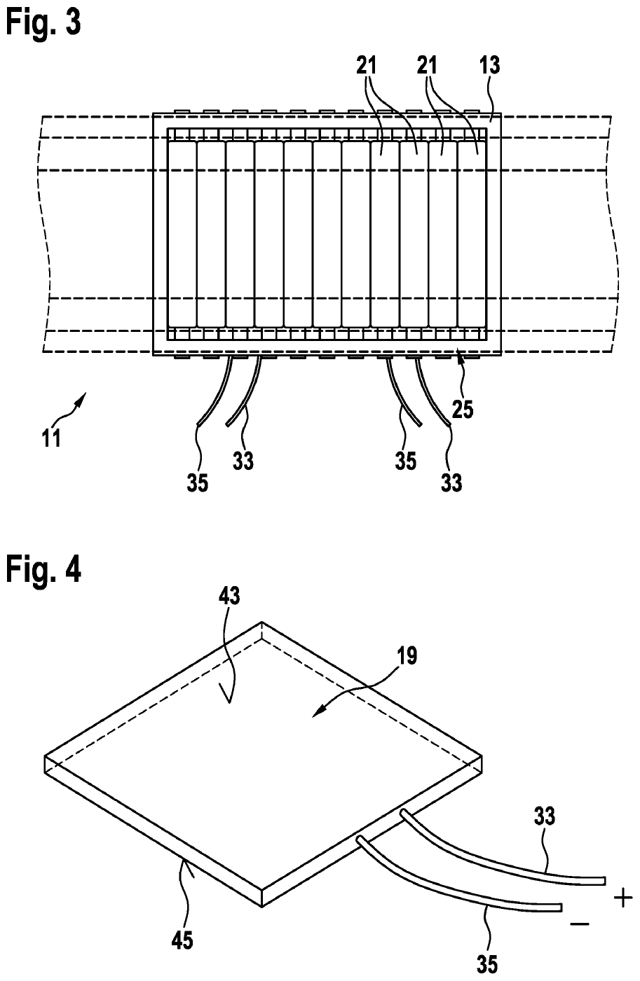

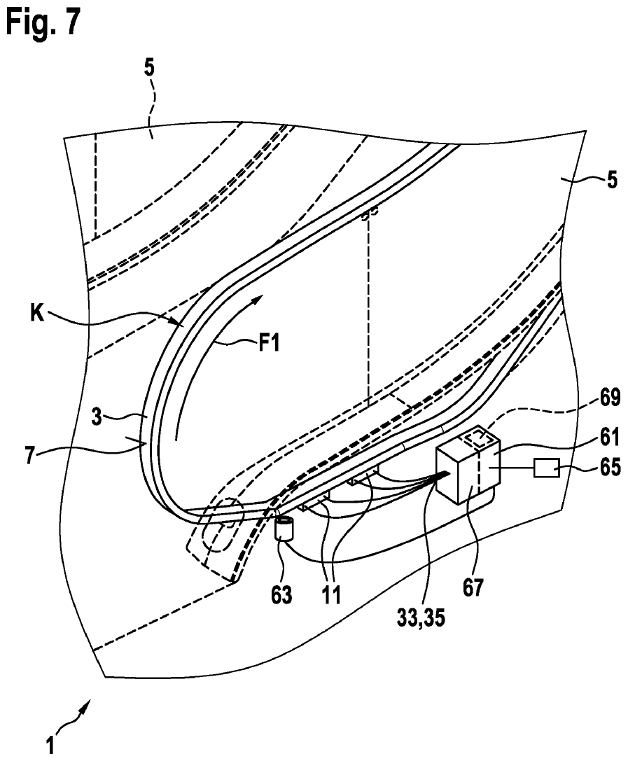

FIG. 1 shows a side view of a handrail temperature-control device 11 which can be installed in an escalator (see FIG. 7) or in a moving walkway in order to cool its movable handrails 3 (shown schematically with a broken line). FIG. 2 shows a cross-section along the line A-A through the handrail temperature-control device 11 of FIG. 1, and FIG. 3 shows a top view of the handrail temperature-control device 11 shown in FIGS. 1 and 2.

In reference to FIG. 1 and FIG. 2, the handrail temperature-control device 11 has a base 15 which serves as a foundation for further components. These further components are in particular a roller arrangement 13 which is arranged on the base 15, and at least one semiconductor cooling element 19. In the present embodiment, two semiconductor cooling elements 19 are present, which are arranged in a recess 39 in the base 15 between the base 15 and the roller arrangement 13. The design of the base 15, the roller arrangement 13, and the semiconductor cooling element 19 is described herein with reference to FIG. 4 to 6.

As can be seen from FIG. 1 to FIG. 3, the roller frame 13 has a plurality of rollers 21 which are arranged at a very small distance S above the semiconductor cooling elements 19 so that the best possible heat exchange between the rollers 21 of the roller frame 15 and the semiconductor cooling elements 19 is ensured. In order to achieve this, the diameters of the rollers 21 and the design of the base 15 are coordinated with one another in such a way that cylindrical surfaces 23 of the rollers 21 have a minimum distance S of 0.0001 mm to 0.5 mm, preferably 0.001 mm to 0.2 mm, or 0.01 mm to 0.1 mm, from a cooling surface 43 (see also FIG. 4) of the semiconductor cooling element 19 arranged in the recess 39.

FIG. 4 shows a three-dimensional view of a semiconductor cooling element 19 of the handrail temperature-control device 11 shown in FIG. 1 to FIG. 3. Semiconductor cooling elements 19, also referred to as Peltier elements, have been known for decades and are used in many fields, such as for example in automotive refrigerators, external cooling devices for cell phones, cold compresses, and the like.

The basis for the Peltier effect is the contact between two semiconductors that have different energy levels (either p- or n-type) of the conduction bands. If a current is passed through two contact points of these materials lying one behind the other, thermal energy may be absorbed at one contact point so that the electron reaches the energetically higher conduction band of the neighboring semiconductor material, resulting in cooling. At the other contact point, the electron falls from a higher to a lower energy level so that energy is released here in the form of heat.

Since n-doped semiconductors have a lower energy level in the conduction band, cooling occurs at the point where electrons transfer from the n-doped to the p-doped semiconductor (technical current flow from the p-doped to the n-doped semiconductor).

A Peltier element consists of two or more small cuboids, each made of p-doped and n-doped semiconductor material (bismuth telluride, silicon germanium), which are alternately connected to one another at the top and bottom by metal bridges (not shown in detail). The metal bridges also form the thermal contact surfaces and are insulated by an overlying foil or a ceramic plate. Two different cuboids are always connected to one another in such a way that they form a series connection. The supplied electrical current flows through all the cuboids one after the other. Depending on the current strength and direction, the connection points on the first side cool down while the connection points on the other side heat up. The current thus pumps heat from a cooling surface 43 to a heating surface 45 and creates a temperature difference between these ceramic plates.

The most common form of Peltier elements consists of two usually square plates made of aluminum oxide ceramic with an edge length of 20 mm to 90 mm and a distance of 3 mm to 5 mm, between which the semiconductor cuboids are soldered. For this purpose, the ceramic surfaces are provided with solderable metal surfaces on their facing surfaces. The semiconductor cooling element 19 thus has a plate-like structure.

Without further measures, the heat difference between the cooling surface 43 or the heating surface 45 of the semiconductor cooling element 19 and the environment (e.g. air) can be compensated for primarily through thermal radiation, and, to a lesser extent, through convection. However, the amount of heat transferred between the cooling surface 43 and the heating surface 45 remains the same, and so does the temperature difference. Depending on the element structure and the supplied current, the temperature difference between the cooling surface 43 and heating surface 45 can be 19 to approximately 70 Kelvin for single-stage semiconductor cooling elements.

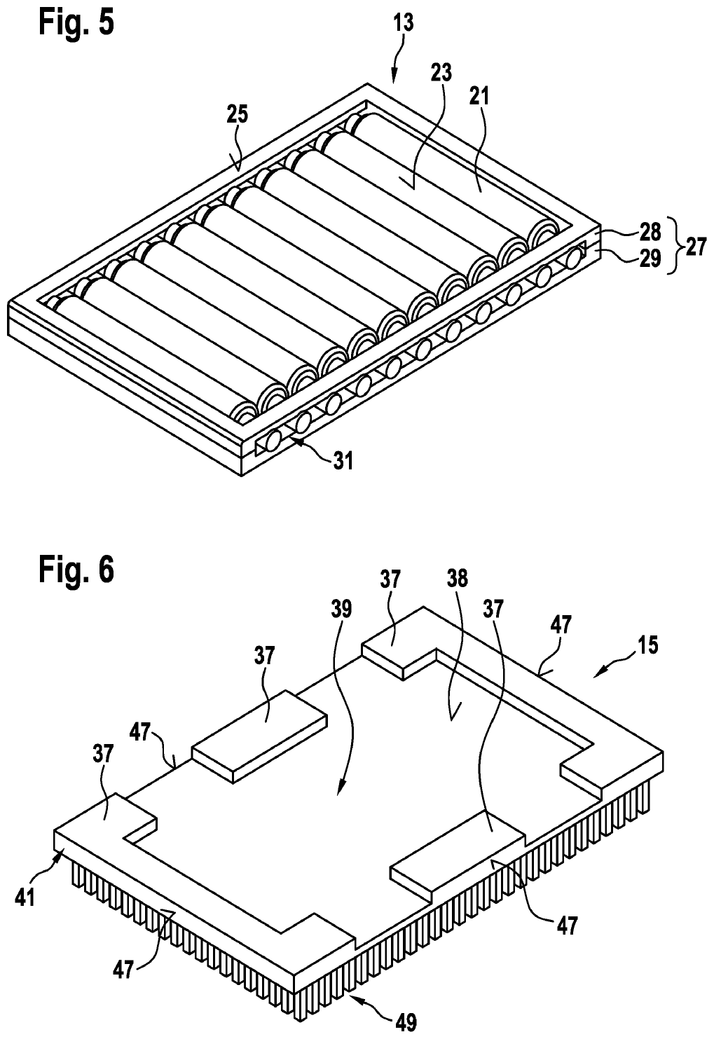

FIG. 5 shows a three-dimensional view of a roller arrangement 13 of the handrail temperature-control device 11 shown in FIG. 1 to 3. The roller arrangement 13 comprises a roller frame 27 and a plurality of rollers 21 which are arranged and rotatably mounted in the roller frame 27. In order to achieve as little friction losses as possible and thus minimal signs of wear on the handrail 3 to be guided over them (see FIG. 1), the rollers 21 are arranged side by side and in parallel to one another with respect to their axes of rotation.

For the purpose of simple assembly of the rollers 21, the roller frame 27 has an upper part 28 and a lower part 29, corresponding bearing shells being formed as bearing points 31 for the rollers 21 in the upper part 28 and lower part 29. The roller frame 27 is preferably made of a material which has good friction bearing properties and low thermal conductivity. The roller frame 27 can be made, for example, of a polymer material or fiber-reinforced polymer material. Of course, the roller frame 27 can also be made of a metal, for example of steel.

The roller frame 27 may frame the rollers 21 laterally, with the cylindrical surfaces 23 of the rollers 21 protruding beyond at least one side surface 25 of the roller frame 27; here the upper part 28. This side surface 25 can run around all the rollers 21 and can be mounted facing a handrail 3 in an escalator 1 (see FIGS. 1 and 7) or in a moving walkway. This ensures that the handrail 3 to be guided over the rollers does not touch the roller frame 27 arranged in a stationary manner in the escalator 1 or in the moving walkway and thereby remove material from the handrail 3.

In order to be able to transfer as much heat as possible from the handrail 3 to the semiconductor cooling element 19, the rollers 21 should have good thermal conductivity properties. The rollers are preferably made primarily of copper, a copper alloy, aluminum, or an aluminum alloy.

Since the heat transfer from the rollers 21 to the cooling side 43 occurs primarily via thermal radiation, the rollers 21 can have a black coating at least on their cylindrical surface 23.

FIG. 6 is a three-dimensional view of a base 15 of the handrail temperature-control device 11 shown in FIG. 1 to 3. The base 15 is made of a thermally conductive material and has a support member 41 and a heat dissipation structure 49. The support member 41 comprises a support surface 38 and four projections 37. The projections 37 are arranged in side regions 47 of the support member 41 on the support surface 38 and protrude from the support surface 38 in a direction facing away from the heat dissipation structure 49. The recess 39 is created in the support member 41 by the projections 37, the dimensions of the recess 39 being designed such that at least one semiconductor cooling element 19 can be arranged therein. In this embodiment, the recess 39 is dimensioned such that two of the semiconductor cooling elements 19 shown in FIG. 4 can be arranged therein.

As shown in FIG. 1 to FIG. 3, the roller arrangement 13 is attached to the projections 37. The heat dissipation structure 49 is thus arranged on a side of the support member 41 facing away from the projections 37 and thus from the roller frame 27 of the roller arrangement 13.

FIG. 7 shows a three-dimensional view of an escalator 1, only shown in part, and a possible arrangement of the handrail temperature-control device 11, shown in FIG. 1 to FIG. 3, in this escalator 1.

Escalators 1 usually have two balustrades 5, on each of which a circumferentially movable handrail 3 is arranged. In order to control the temperature of a grip surface 7 of the handrail 3, at least one handrail temperature-control device 11 is arranged with its roller arrangement 13 (see FIG. 1 to FIG. 6) under the handrail 3. In this case, the grip surface 7 of the handrail 3 is guided over the rollers 21 of the roller arrangement 13 and is in contact therewith.

As shown in the present embodiment, two handrail temperature-control devices 11 arranged one behind the other are provided for each handrail 3. These are arranged upstream relative to a starting point K of the handrail 3 along a direction of movement F1 of the circulating handrail 3. The starting point K in this case is the approximate point on the handrail 3 that a passenger first touches with their hand when entering the escalator 1. In other words, the handrail temperature-control devices 11 are placed such that they are not too far away from the starting point K at which a passenger grips the handrail 3. Preferably, the assembly instructions for assembling the handrail temperature-control device 11 specify that the distance between the handrail temperature-control device 11 and the starting point K along the direction of movement F1 of the handrail 3 is within a certain range.

The handrail temperature-control device 11 also comprises a current supply 67 which may supply current to the semiconductor cooling element 11 as required. Specifically, a direct current may be supplied via the current lines 33, 35, and care should be taken to ensure the correct polarity. Furthermore, the handrail temperature-control device 11 has a temperature-regulating module 61 which may regulate the output power of the current supply 67 to be supplied to the semiconductor cooling element 11.

For this purpose, the temperature-regulating module 61 comprises a handrail temperature measurement sensor 63 and a processor 69 having suitable processing software. The handrail temperature measurement sensor 63 may be used to measure the temperature of the handrail 3 and transmit its measurement signals continuously or periodically to the processor 69. The temperature may be expediently measured at a point of the handrail 3 which is arranged between the handrail temperature-control device 11 and the starting point K described above so that the temperature of the cooled down grip surface 7 can be detected. The processor 69 may process the measurement signals transmitted to it by the handrail temperature-measuring sensor 63 and can be configured to regulate the output power of the current supply 67 transmitted to the semiconductor cooling element 19 as a function of the temperature of the handrail 3 measured by the handrail temperature measurement sensor 63. This may allow the temperature of the handrail 3 to be regulated in such a way that it creates a pleasant feel for the passenger.

In order to create a pleasant feel of the handrail 3 also with respect to the ambient temperature of the escalator 1, the temperature-regulating module 61 has an ambient temperature measurement sensor 65, the ambient temperature measurement sensor 65 being used to measure the ambient temperature of the escalator 1 or the moving walkway. The processor 69 may be further configured to regulate the output power of the current supply 67 transmitted to the semiconductor cooling element 11 as a function of a predetermined difference to the outside temperature and taking into account the temperature of the handrail 3 measured by the handrail temperature measurement sensor 63.

Although FIG. 1 to 7 show different aspects of the present disclosure on the basis of a passenger transport system designed as an escalator 1, it is obvious that the described handrail temperature-control device 11 can equally be used in the case of obliquely-arranged moving walkways or horizontally-arranged moving walkways. As already explained herein, semiconductor cooling elements 19 have a cooling surface 43 and a heating surface 45. Their property of being a heating surface 45 or cooling surface 43 depends on the polarity of the direct current supplied via the current lines 33, 35. It is therefore obvious that the present handrail temperature-control device 11 can be used not only as a handrail cooling device but also as a handrail heating device when the polarity is reversed with the temperature-regulating module 61 without changing the present design. If necessary, the roller frame 27 of the roller arrangement 13 can be made of a temperature-resistant material.

Finally, it should be noted that terms such as “having,” “comprising,” etc. do not preclude other elements or steps, and terms such as “a” or “one” do not preclude a plurality. Furthermore, it should be noted that features or steps which have been described with reference to one of the above embodiments may also be used in combination with other features or steps of other embodiments described above. Reference signs in the claims should not be considered to be limiting.

1-15. (canceled)

16. A handrail temperature-control device for a movably arranged handrail of an escalator or a moving walkway, the handrail temperature-control device comprising:
a base;
a roller arrangement arranged on the base; and
a semiconductor cooling element arranged in a recess between the base and the roller arrangement.

17. The handrail temperature-control device of claim 16, wherein the roller arrangement comprises a roller frame and a plurality of rollers wherein the plurality of rollers is arranged side by side and parallel to one another with respect to their axes of rotation and are rotatably mounted in the roller frame.

18. The handrail temperature-control device of claim 17, wherein the roller frame frames the rollers laterally, and wherein cylindrical surfaces of the rollers protrude beyond at least one side surface of the roller frame.

19. The handrail temperature-control device of claim 16, wherein the base is made of a thermally conductive material and comprises a support member and a heat dissipation structure, wherein the heat dissipation structure is arranged on a side of the support member facing away from the roller frame.

20. The handrail temperature-control device of claim 19, wherein the support member comprises a support surface and at least one projection, the projection being arranged in side regions of the support member on the support surface and protruding from the support surface in a direction facing away from the heat dissipation structure and at least partially delimiting the recess.

21. The handrail temperature-control device according to claim 20, wherein at least two semiconductor cooling elements are arranged in the recess.

22. The handrail temperature-control device of claim 16, wherein the semiconductor cooling element comprises a plate-like structure, and the roller frame, the diameters of the rollers, and the at least one projection are coordinated with one another in such a way that cylindrical surfaces of the rollers have a minimum distance of 0.0001 mm to 0.5 mm from a cooling surface of the semiconductor cooling element arranged in the recess.

23. The handrail temperature-control device of claim 17, wherein the rollers are made of copper, a copper alloy, aluminum, and/or an aluminum alloy.

24. The handrail temperature-control device of claim 23, wherein the rollers have a black coating at least on their cylindrical surface.

25. The handrail temperature-control device of claim 17, wherein the base is made of a thermally conductive material and comprises a support member and a heat dissipation structure, wherein the heat dissipation structure is arranged on a side of the support member facing away from the roller frame.

26. The handrail temperature-control device of claim 17, wherein the base is made of a thermally conductive material and comprises a support member and a heat dissipation structure, wherein the heat dissipation structure is arranged on a side of the support member facing away from the roller frame.

27. The handrail temperature-control device of claim 17, wherein the semiconductor cooling element comprises a plate-like structure, and the roller frame, the diameters of the rollers, and the at least one projection are coordinated with one another in such a way that cylindrical surfaces of the rollers have a minimum distance of 0.0001 mm to 0.5 mm from a cooling surface of the semiconductor cooling element arranged in the recess.

28. An escalator or moving walkway comprising:
at least one balustrade;
a handrail arranged around the balustrade; and
at least one handrail temperature-control device of claim 16 arranged under the handrail configured to control the temperature of the grip surface of the handrail, the grip surface positioned over the roller arrangement and being in contact therewith.

29. The escalator or moving walkway of claim 28, wherein the at least one handrail temperature-control device is arranged upstream relative to a starting point of the passenger touching the handrail along a direction of movement of the handrail.

30. The escalator or moving walkway of claim 28, wherein each handrail comprises at least two handrail temperature-control devices, wherein the at least two handrail temperature-control devices are arranged at intervals along the direction of movement of the handrail.

31. The escalator or moving walkway of claim 28, wherein the handrail temperature-control device further comprises a current supply configured to supply current to the semiconductor cooling element, and further comprises a temperature-regulating module configured to regulate the output power of the current supply to be supplied to the semiconductor cooling element.

32. The escalator or moving walkway of claim 31, wherein the temperature-regulating module comprises a handrail temperature measurement sensor and a processor, wherein the handrail temperature measurement sensor is configured to measure the temperature of the handrail and the processor is configured to process measurement signals transmitted to it from the handrail temperature measurement sensor, and wherein the processor is configured to regulate the output power of the current supply transmitted to the semiconductor cooling element as a function of the temperature of the handrail measured by the handrail temperature measurement sensor.

33. The escalator or moving walkway of claim 32, wherein the temperature-regulating module comprises an ambient temperature measurement sensor, the ambient temperature measurement sensor configured to measure the ambient temperature of the escalator or the moving walkway, and the processor configured to regulate the output power of the current supply transmitted to the semiconductor cooling element as a function of a predetermined difference from the outside temperature and taking into account the temperature of the handrail measured by the handrail temperature measurement sensor.

34. The escalator or moving walkway of claim 29, wherein each handrail comprises at least two handrail temperature-control devices, wherein the at least two handrail temperature-control devices are arranged at intervals along the direction of movement of the handrail.

35. The escalator or moving walkway of claim 29, wherein the handrail temperature-control device further comprises a current supply configured to supply current to the semiconductor cooling element, and further comprises a temperature-regulating module configured to regulate the output power of the current supply to be supplied to the semiconductor cooling element.
